(19) United States
(12) Patent Application Publication
(10) Pub. No.: US 2020/0257176 A1
(43) Pub. Date: Aug. 13, 2020

(54) ARRAY SUBSTRATE, MANUFACTURING METHOD THEREOF, AND DISPLAY DEVICE

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Jie Zhang, Beijing (CN); Lu Yang, Beijing (CN); Dawei Shi, Beijing (CN); Jun Fan, Beijing (CN)

(21) Appl. No.: 15/777,178

(22) PCT Filed: Nov. 9, 2017
(86) PCT No.: PCT/CN2017/110125

§ 371 Date: May 17, 2018

(30) Foreign Application Priority Data
May 11, 2017 (CN) 201710331516.8

(51) Int. Cl. G02F 1/1362; G02F 1/1343; G02F 1/1368; H01L 27/12

(52) U.S. Cl. CPC G02F 1/136286; G02F 1/13439; G02F 1/1368; G02F 2001/136295; H01L 27/1248; H01L 27/1259; G02F 2001/13685; H01L 27/124

(57) ABSTRACT

The present disclosure in some embodiments provides an array substrate, a manufacturing method thereof, and a display device. The array substrate includes: a plurality of gate lines and a plurality of data lines defining a plurality of pixel regions; and a plurality of insulation layers including at least one hollowed-out insulation layer. A portion of the hollowed-out insulation layer at a corresponding pixel region is provided with a hollowed-out region. According to the present disclosure, it is able to reduce adverse impact of the insulation layers at the pixel regions on a light transmittance, thereby to improve a display effect.

### CROSS-REFERENCE TO RELATED APPLICATION

The present application is the U.S. national phase of PCT Application No. PCT/CN2017/110125 filed on Nov. 9, 2017, which claims a priority of the Chinese patent application No. 201710331516.8 filed on May 11, 2017, which is incorporated herein by reference in its entirety.

### TECHNICAL FIELD

The present disclosure relates to the field of display technology, in particular to an array substrate, a manufacturing method thereof, and a display device.

### BACKGROUND

Along with the maturation and development of the liquid crystal display (LCD) panel industry, a liquid crystal display panel with high quality, e.g., high brightness, high contrast and high resolution, is highly demanded. However, in terms of a current manufacturing process, a low light transmittance has become a bottleneck for the high-resolution LCD panel.

Especially, an array substrate of the LCD panel with an advanced super dimension switching (ADS) mode includes a plurality of insulation layers, e.g., a gate insulation layer, an insulation layer arranged between a source/drain metal layer and a first transparent electrode layer, and another insulation layer arranged between the first transparent electrode layer and a second transparent electrode layer. In addition, in the case that thin film transistors (TFTs) of the array substrate are of a top-gate type, the array substrate further includes another insulation layer between a gate metal layer and the source/drain metal layer. Due to the plurality of insulation layers, the light transmittance of the array substrate as well as a display effect may be adversely affected.

### SUMMARY

### (1) Technical Problem to be Solved

An object of the present disclosure is to provide an array substrate, a manufacturing method thereof, and a display device, so as to improve the light transmittance of the array substrate.

### (2) Technical Solution

In one aspect, the present disclosure provides in some embodiments an array substrate, including: a plurality of gate lines and a plurality of data lines defining a plurality of pixel regions; and a plurality of insulation layers including at least one hollowed-out insulation layer. A portion of the hollowed-out insulation layer at a corresponding pixel region is provided with a hollowed-out region.

In a possible embodiment of the present disclosure, the array substrate further includes a gate insulation layer, and the hollowed-out insulation layer includes the gate insulation layer.

In a possible embodiment of the present disclosure, the array substrate further includes a source/drain metal layer, a first transparent electrode layer and a second insulation layer arranged between the source/drain metal layer and the first transparent electrode layer, and the hollowed-out insulation layer includes the second insulation layer.

In a possible embodiment of the present disclosure, the array substrate is a top-gate array substrate including a source/drain metal layer, a gate metal layer and a first insulation layer arranged between the gate metal layer and the source/drain metal layer, and the hollowed-out insulation layer includes the first insulation layer.

In a possible embodiment of the present disclosure, the array substrate further includes an active layer, and the first insulation layer is provided with a hollowed-out region at a position where the source/drain metal layer is lapped onto the active layer.

In a possible embodiment of the present disclosure, the portion of the hollowed-out insulation layer at the corresponding pixel region is fully hollowed out.

In a possible embodiment of the present disclosure, the portion of the hollowed-out insulation layer at each pixel region is provided with the hollowed-out region.

In a possible embodiment of the present disclosure, the portions of the hollowed-out insulation layer at a part of pixel regions are provided with the hollowed-out regions respectively, and the portions of the hollowed-out insulation layer at the other part of pixel regions are not provided with any hollowed-out regions.

In a possible embodiment of the present disclosure, the hollowed-out region of the first insulation layer at the position where the source/drain metal layer is lapped onto the active layer and the hollowed-out region of the first insulation layer at the other position in the pixel region are formed through one single patterning process.

In a possible embodiment of the present disclosure, the hollowed-out region of the first insulation layer at the position where the source/drain metal layer is lapped onto the active layer and the hollowed-out region of the first insulation layer at the other position in the pixel region are formed in one piece.

In another aspect, the present disclosure provides in some embodiments a display device including the above-mentioned array substrate.

In yet another aspect, the present disclosure provides in some embodiments a method for manufacturing an array substrate, including a step of forming a gate metal layer, a source/drain metal layer and a plurality of insulation layers. The gate metal layer includes a plurality of gate lines, the source/drain metal layer includes a plurality of data lines, the plurality of gate lines and the plurality of data lines define a plurality of pixel regions, the plurality of insulation layers includes at least one hollowed-out insulation layer, and a portion of the hollowed-out insulation layer at a corresponding pixel region is provided with a hollowed-out region.

In a possible embodiment of the present disclosure, the step of forming the plurality of insulation layers includes forming a gate insulation layer, and the hollowed-out insulation layer includes the gate insulation layer.

In a possible embodiment of the present disclosure, the method further includes forming a first transparent electrode layer. The step of forming the plurality of insulation layers includes forming a second insulation layer between the source/drain metal layer and the first transparent electrode layer, and the hollowed-out insulation layer includes the second insulation layer.

In a possible embodiment of the present disclosure, in the case that the array substrate is a top-gate array substrate, the step of forming the plurality of insulation layers includes forming a first insulation layer between the gate metal layer and the source/drain metal layer, and the hollowed-out insulation layer includes the first insulation layer.

### (3) Beneficial Effect

According to the embodiments of the present disclosure, the portion of the at least one insulation layer at the corresponding pixel region of the array substrate is provided with the hollowed-out region, so as to reduce adverse impact of the insulation layers at the pixel region on a light transmittance, thereby to improve a display effect.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic view showing a conventional ADS-mode array substrate;

FIG. 2 is a schematic view showing an ADS-mode array substrate according to one embodiment of the present disclosure;

FIG. 3 is another schematic view showing the ADS-mode array substrate according to one embodiment of the present disclosure; and

FIG. 4 is a flow chart of a method for manufacturing the array substrate according to one embodiment of the present disclosure.

### DETAILED DESCRIPTION OF THE EMBODIMENTS

The present disclosure will be described hereinafter in conjunction with the drawings and embodiments. The following embodiments are for illustrative purposes only, but shall not be used to limit the scope of the present disclosure.

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

The present disclosure provides in some embodiments an array substrate, which includes: a plurality of gate lines and a plurality of data lines defining a plurality of pixel regions; and a plurality of insulation layers including at least one hollowed-out insulation layer. A portion of the hollowed-out insulation layer at a corresponding pixel region is provided with a hollowed-out region.

According to the array substrate in the embodiments of the present disclosure, the portion of the at least one insulation layer at the corresponding pixel region of the array substrate is provided with the hollowed-out region, so as to reduce adverse impact of the insulation layers at the pixel region on a light transmittance, thereby to improve a display effect.

In the embodiments of the present disclosure, the portion of the hollowed-out insulation layer at each pixel region may be provided with the hollowed-out region. Of course, in some other cases, the portions of the hollowed-out insulation layer at a part of pixel regions may be provided with the hollowed-out regions respectively, and the portions of the hollowed-out insulation layer at the other part of pixel regions may not be provided with any hollowed-out regions.

The array substrate further includes a gate insulation layer. In a possible embodiment of the present disclosure, the hollowed-out insulation layer may include the gate insulation layer. In other words, a portion of the gate insulation layer at the corresponding pixel region is provided with the hollowed-out region, so as to reduce adverse impact of the insulation layers at the pixel region on the light transmittance, thereby to improve the display effect.

The array substrate further includes a source/drain metal layer, a first transparent electrode layer and a second insulation layer arranged between the source/drain metal layer and the first transparent electrode layer. The source/drain metal layer may include source electrodes, drain electrodes and the data lines. The first transparent electrode layer may be a pixel electrode layer or a common electrode layer. In a possible embodiment of the present disclosure, the hollowed-out insulation layer may include the second insulation layer. In other words, a portion of the second insulation layer at the corresponding pixel region is provided with the hollowed-out region, so as to reduce adverse impact of the second insulation layer at the pixel region on the light transmittance, thereby to improve the display effect.

In a possible embodiment of the present disclosure, each drain electrode is lapped onto the pixel electrode layer through the hollowed-out region of the second insulation layer at the corresponding pixel region, i.e., it is unnecessary to form a via-hole in the second insulation layer for connecting the drain electrode and the pixel electrode layer. As a result, it is unnecessary to provide any additional mask plate, thereby to reduce the manufacture cost.

Of course, in some other embodiments of the present disclosure, the hollowed-out insulation layer may include the gate insulation layer and the second insulation layer, so as to further reduce adverse impact of the insulation layers at the corresponding pixel region on the light transmittance, thereby to improve the display effect.

In the case that the array substrate is a top-gate array substrate, it may include the source/drain metal layer, the gate metal layer and a first insulation layer arranged between the gate metal layer and the source/drain metal layer. The source/drain metal layer may include source electrodes, drain electrodes and the data lines. The gate metal layer may include gate electrodes and the gate lines. In a possible embodiment of the present disclosure, the hollowed-out insulation layer includes the first insulation layer. In other words, a portion of the first insulation layer at the corresponding pixel region is provided with the hollowed-out region, so as to reduce adverse impact of the first insulation layer at the pixel region on the light transmittance, thereby to improve the display effect.

Of course, in some other embodiments of the present disclosure, the hollowed-out insulation layer may include any two or three of the gate insulation layer, the first insulation layer and the second insulation layer, so as to further reduce adverse impact of the insulation layers at the corresponding pixel region on the light transmittance, thereby to improve the display effect.

The array substrate further includes an active layer. In a possible embodiment of the present disclosure, the first insulation layer is provided with the hollowed-out region at a position where the source/drain metal layer is lapped onto the active layer, so as to facilitate the connection of the source/drain metal layer to the active layer. The hollowed-out region of the first insulation layer at the position where the source/drain metal layer is lapped onto the active layer and the hollowed-out region of the first insulation layer at the other position in the pixel region may be formed through one single patterning process. As a result, it is unnecessary to form a via-hole in the first insulation layer for connecting the source/drain metal layer to the active layer.

In a possible embodiment of the present disclosure, the hollowed-out region of the first insulation layer at the position where the source/drain metal layer is lapped onto the active layer and the hollowed-out region of the first insulation layer at the other position in the pixel region are formed in one piece.

In a possible embodiment of the present disclosure, the portion of the hollowed-out insulation layer at the corresponding pixel region is fully hollowed out, so as to reduce adverse impact of the insulation layers on the light transmittance to the maximum extent, thereby to improve the display effect.

The present disclosure further provides in some embodiments a display device including the above-mentioned array substrate.

The display device may be a display panel or a display element including the display panel and a driving circuit. In a possible embodiment of the present disclosure, the display device is a liquid crystal display (LCD) device.

The present disclosure further provides in some embodiments a method for manufacturing an array substrate, which includes a step of forming a gate metal layer, a source/drain metal layer and a plurality of insulation layers. The gate metal layer includes a plurality of gate lines, the source/drain metal layer includes a plurality of data lines, the plurality of gate lines and the plurality of data lines define a plurality of pixel regions, the plurality of insulation layers includes at least one hollowed-out insulation layer, and a portion of the hollowed-out insulation layer at a corresponding pixel region is provided with a hollowed-out region.

In a possible embodiment of the present disclosure, the step of forming the plurality of insulation layers includes forming a gate insulation layer, and the hollowed-out insulation layer includes the gate insulation layer.

In a possible embodiment of the present disclosure, the method further includes forming a first transparent electrode layer. The step of forming the plurality of insulation layers includes forming a second insulation layer between the source/drain metal layer and the first transparent electrode layer, and the hollowed-out insulation layer includes the second insulation layer.

In a possible embodiment of the present disclosure, in the case that the array substrate is a top-gate array substrate, the step of forming the plurality of insulation layers includes forming a first insulation layer between the gate metal layer and the source/drain metal layer, and the hollowed-out insulation layer includes the first insulation layer.

The structure of the array substrate will be described hereinafter in conjunction with the embodiments.

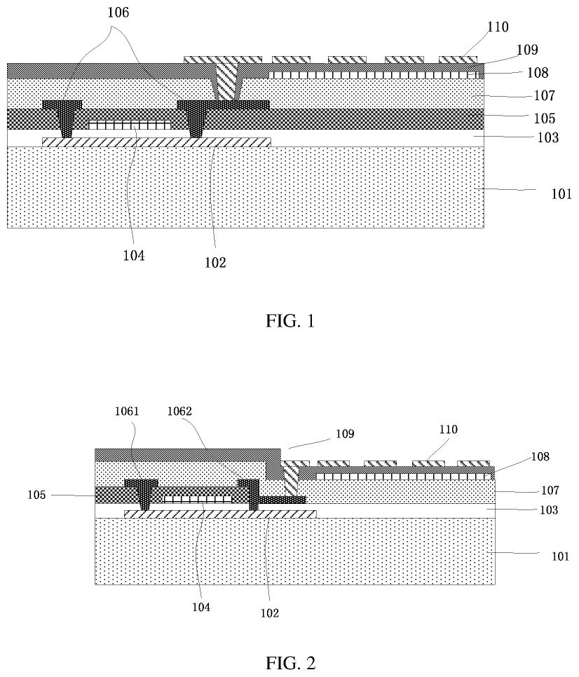

Referring to FIG. 1 which is a schematic view showing a conventional ADS-mode array substrate, the array substrate includes a base substrate 101, an active layer 102, a gate insulation layer 103, a gate metal layer 104, a first insulation layer 105, a source/drain metal layer 106, a second insulation layer 107, a common electrode layer 108, a third insulation layer 109 and a pixel electrode layer 110. As shown in FIG. 1, the array substrate includes a plurality of insulation layers (i.e., the gate insulation layer 103, the first insulation layer 105, the second insulation layer 107 and the third insulation layer 109), so the light transmittance of the array substrate may be adversely affected.

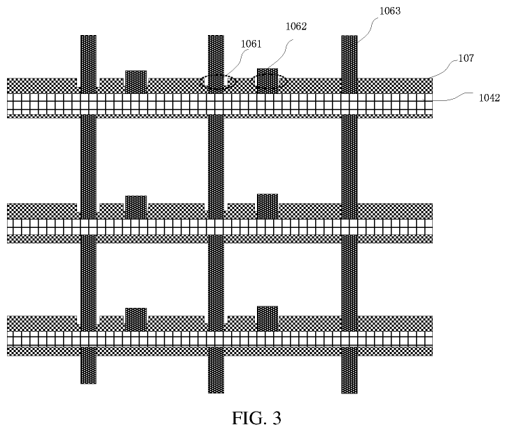

Referring to FIG. 2 which is a schematic view showing an ADS-mode array substrate in the embodiments of the present disclosure and FIG. 3 which is another schematic view showing the ADS-mode array substrate in the embodiments of the present disclosure, the array substrate includes, but not limited to, a base substrate 101, an active layer 102, a gate insulation layer 103, a gate metal layer 104, a first insulation layer 105, a source/drain metal layer, a second insulation layer 107, a common electrode layer 108, a third insulation layer 109 and a pixel electrode layer 110. The gate metal layer includes gate electrodes 104 and gate lines 1042. The source/drain metal layer includes source electrodes 1061, drain electrodes 1062 and data lines 1063. The gate lines 1042 and the data lines 1063 define a plurality of pixel regions. A portion of the first insulation layer 105 at a corresponding pixel region is provided with a hollowed-out region.

According to the embodiments of the present disclosure, the portion of the first insulation layer 105 at the corresponding pixel region of the array substrate is provided with the hollowed-out region, so as to reduce adverse impact of the first insulation layer 105 on the light transmittance, thereby to improve the display effect.

Referring to FIG. 3, the first insulation layer 105 is further provided with the hollowed-out region at a position where each drain electrode 1062 is lapped onto the active layer 102 (i.e., a position shown by a dotted box in FIG. 3), so as to facilitate the connection of the source/drain metal layer to the active layer.

As mentioned above, the first insulation layer 105 between the gate metal layer and the source/drain metal layer is provided with the hollowed-out region at the corresponding pixel region. Of course, in some other embodiments of the present disclosure, the second insulation layer 107 between the source/drain metal layer and the common electrode layer 108 may be provided with the hollowed-out region at the corresponding pixel region. Alternatively, both the first insulation layer 105 and the second insulation layer 107 may be provided with the hollowed-out regions at the corresponding pixel regions.

In the embodiments of the present disclosure, the common electrode layer 108 and the pixel electrode layer 110 may be interchangeable with each other.

The present disclosure further provides in some embodiments a display device including the above-mentioned array substrate. The features of the array substrate included in the display device may refer to those mentioned above, and thus will not be particularly defined herein.

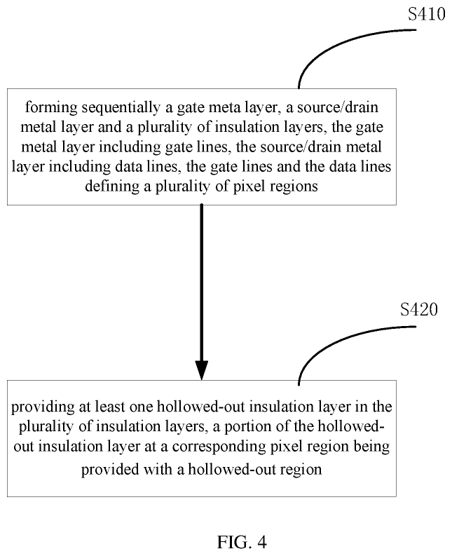

The present disclosure further provides in some embodiments a method for manufacturing an array substrate which, as shown in FIG. 4, includes: Step S410 of forming a gate meta layer, a source/drain metal layer and a plurality of insulation layers, the gate metal layer including gate lines, the source/drain metal layer including data lines, the gate lines and the data lines defining a plurality of pixel regions; and Step S420 of forming at least one hollowed-out insulation layer in the plurality of insulation layers, a portion of the hollowed-out insulation layer at a corresponding pixel region being provided with a hollowed-out region.

In a possible embodiment of the present disclosure, the step of forming the plurality of insulation layers includes forming a gate insulation layer, and the hollowed-out insulation layer includes the gate insulation layer.

In a possible embodiment of the present disclosure, the method may further include forming a first transparent electrode layer. The step of forming the plurality of insulation layers includes forming a second insulation layer between the source/drain metal layer and the first transparent electrode layer. The hollowed-out insulation layer includes the second insulation layer.

In a possible embodiment of the present disclosure, in the case that the array substrate is a top-gate array substrate, the step of forming the plurality of insulation layers includes forming a first insulation layer between the gate metal layer and the source/drain metal layer. The hollowed-out insulation layer includes the first insulation layer.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

The above are merely the preferred embodiments of the present disclosure, but the present disclosure is not limited thereto. Obviously, a person skilled in the art may make further modifications and improvements without departing from the spirit of the present disclosure, and these modifications and improvements shall also fall within the scope of the present disclosure.

1. An array substrate, comprising:
a plurality of gate lines and a plurality of data lines defining a plurality of pixel regions; and
a plurality of insulation layers including at least one hollowed-out insulation layer,
wherein a portion of the hollowed-out insulation layer at a corresponding pixel region is provided with a hollowed-out region.

2. The array substrate according to claim 1, further comprising a gate insulation layer, wherein the hollowed-out insulation layer comprises the gate insulation layer.

3. The array substrate according to claim 1, further comprising a source/drain metal layer, a first transparent electrode layer and a second insulation layer arranged between the source/drain metal layer and the first transparent electrode layer, wherein the hollowed-out insulation layer comprises the second insulation layer.

4. The array substrate according to claim 1, wherein the array substrate is a top-gate array substrate and comprises a source/drain metal layer, a gate metal layer and a first insulation layer arranged between the gate metal layer and the source/drain metal layer, wherein the hollowed-out insulation layer comprises the first insulation layer.

5. The array substrate according to claim 4, further comprising an active layer, wherein the first insulation layer is provided with the hollowed-out region at a position where the source/drain metal layer is lapped onto the active layer.

6. The array substrate according to claim 1, wherein the portion of the hollowed-out insulation layer at the corresponding pixel region is fully hollowed out.

7. The array substrate according to claim 1, wherein portions of the hollowed-out insulation layer at each pixel region are provided with hollowed-out regions.

8. The array substrate according to claim 1, wherein portions of the hollowed-out insulation layer at a first part of the pixel regions are provided with hollowed-out regions respectively, and portions of the hollowed-out insulation layer at a second part of the pixel regions are not provided with any hollowed-out regions.

9. The array substrate according to claim 5, wherein the first insulation layer is provided with the hollowed-out region at the position where the source/drain metal layer is lapped onto the active layer and at another position in the pixel region, wherein the hollowed-out region at both positions is formed through one single patterning process.

10. The array substrate according to claim 5, wherein the first insulation layer is provided with the hollowed-out region at the position where the source/drain metal layer is lapped onto the active layer and at another position in the pixel region, wherein the hollowed-out region at both positions is formed in one piece.

11. A display device, comprising an array substrate, the array substrate comprising:
a plurality of gate lines and a plurality of data lines defining a plurality of pixel regions; and
a plurality of insulation layers including at least one hollowed-out insulation layer,
wherein a portion of the hollowed-out insulation layer at a corresponding pixel region is provided with a hollowed-out region.

12. A method for manufacturing an array substrate, comprising:
forming sequentially a gate metal layer, a source/drain metal layer and a plurality of insulation layers, wherein the gate metal layer comprises a plurality of gate lines, the source/drain metal layer comprises a plurality of data lines, and the plurality of gate lines and the plurality of data lines define a plurality of pixel regions; and
forming at least one hollowed-out insulation layer in the plurality of insulation layers, wherein a portion of the hollowed-out insulation layer at a corresponding pixel region is provided with a hollowed-out region.

13. The method according to claim 12, wherein the forming the plurality of insulation layers comprises forming a gate insulation layer, and the hollowed-out insulation layer comprises the gate insulation layer.

14. The method according to claim 12, further comprising forming a first transparent electrode layer, wherein forming the plurality of insulation layers comprises forming a second insulation layer between the source/drain metal layer and the first transparent electrode layer, and the hollowed-out insulation layer comprises the second insulation layer.

15. The method according to claim 12, wherein the array substrate is a top-gate array substrate, forming the plurality of insulation layers comprises forming a first insulation layer between the gate metal layer and the source/drain metal layer, and the hollowed-out insulation layer comprises the first insulation layer.

16. The display device according to claim 11, wherein the array substrate further comprises a gate insulation layer, wherein the hollowed-out insulation layer comprises the gate insulation layer.

17. The display device according to claim 11, wherein the array substrate further comprises a source/drain metal layer, a first transparent electrode layer and a second insulation layer arranged between the source/drain metal layer and the first transparent electrode layer, wherein the hollowed-out insulation layer comprises the second insulation layer.

18. The display device according to claim 11, wherein the array substrate is a top-gate array substrate and comprises a source/drain metal layer, a gate metal layer and a first insulation layer arranged between the gate metal layer and the source/drain metal layer, wherein the hollowed-out insulation layer comprises the first insulation layer; and
wherein the array substrate further comprises an active layer, wherein the first insulation layer is provided with the hollowed-out region at a position where the source/drain metal layer is lapped onto the active layer.

19. The display device according to claim 11, wherein:
the portion of the hollowed-out insulation layer at the corresponding pixel region is fully hollowed out; or
portions of the hollowed-out insulation layer at each pixel region are provided with hollowed-out regions; or
portions of the hollowed-out insulation layer at a first part of the pixel regions are provided with hollowed-out regions respectively, and portions of the hollowed-out insulation layer at a second part of the pixel regions are not provided with any hollowed-out regions.

20. The display device according to claim 18, wherein the first insulation layer is provided with the hollowed-out region at the position where the source/drain metal layer is lapped onto the active layer and at another position in the pixel region, and wherein the hollowed-out region at both positions is formed through one single patterning process and is formed in one piece.
